(19) United States
(12) Patent Application Publication
(10) Pub. No.: US 2018/0269634 A1
(43) Pub. Date: Sep. 20, 2018

(54) POWER DETECTION AND ACTIVATION OUTLET ASSEMBLY

(71) Applicant: Gregory Tompkins, Lancaster, CA (US)

(72) Inventor: Gregory Tompkins, Lancaster, CA (US)

(21) Appl. No.: 15/459,493

(22) Filed: Mar. 15, 2017

(51) Int. Cl. H01R 13/70; H01R 25/00; H01R 13/66; G01R 19/165; G01R 15/14

(52) U.S. Cl. CPC H01R 13/70; H01R 25/006; G01R 15/14; G01R 19/16571; H01R 13/6683

(57) ABSTRACT

A power detection and activation outlet assembly includes a housing having a plurality of power ports therein. The plurality of power ports includes a primary outlet and a secondary outlet. A power plug, for plugging into an electrical outlet, is in electrical communication with each of the power ports. A switch is in electrical communication with the primary outlet. The switch is in a normally closed position such that electricity is not provided to the primary outlet by the power plug. A current sensor is in electrical communication with the switch. The current sensor actuates the switch to an open position when the current sensor detects a current greater than 1.0 ampere. The current sensor is positioned on a power cord to detect current in the power cord.

### CROSS-REFERENCE TO RELATED APPLICATIONS

Not Applicable

### STATEMENT REGARDING FEDERALLY SPONSORED RESEARCH OR DEVELOPMENT

Not Applicable

### THE NAMES OF THE PARTIES TO A JOINT RESEARCH AGREEMENT

Not Applicable

### INCORPORATION-BY-REFERENCE OF MATERIAL SUBMITTED ON A COMPACT DISC OR AS A TEXT FILE VIA THE OFFICE ELECTRONIC FILING SYSTEM.

Not Applicable

### STATEMENT REGARDING PRIOR DISCLOSURES BY THE INVENTOR OR JOINT INVENTOR

Not Applicable

### BACKGROUND OF THE INVENTION

### (1) Field of the Invention

### (2) Description of Related Art Including Information Disclosed Under 37 CFR 1.97 and 1.98

The disclosure and prior art relates to power outlet and current sensing combination devices and more particularly pertains to a new power outlet and current sensing combination device for turning the power on or off of a vacuum plugged into an outlet in response to the turning on or off of a power tool plugged into a different outlet.

### BRIEF SUMMARY OF THE INVENTION

An embodiment of the disclosure meets the needs presented above by generally comprising a housing having a plurality of power ports therein. The plurality of power ports includes a primary outlet and at least one secondary outlet that is mounted in the housing. A power plug is coupled to the housing and is in electrical communication with each of the power ports. The power plug is configured to be plugged into an electrical outlet. A switch is in electrical communication with the primary outlet. The switch is in a normally closed position such that electricity is not provided to the primary outlet by the power plug. A current sensor is in electrical communication with the switch. The current sensor actuates the switch to an open position when the current sensor detects a current greater than 1.0 ampere. The current sensor is positioned outside of the housing to facilitate positioning of the current sensor on a power cord.

There has thus been outlined, rather broadly, the more important features of the disclosure in order that the detailed description thereof that follows may be better understood, and in order that the present contribution to the art may be better appreciated. There are additional features of the disclosure that will be described hereinafter and which will form the subject matter of the claims appended hereto.

The objects of the disclosure, along with the various features of novelty which characterize the disclosure, are pointed out with particularity in the claims annexed to and forming a part of this disclosure.

### BRIEF DESCRIPTION OF SEVERAL VIEWS OF THE DRAWING(S)

The disclosure will be better understood and objects other than those set forth above will become apparent when consideration is given to the following detailed description thereof. Such description makes reference to the annexed drawings wherein:

FIG. 1 is a top perspective view of a power detection and activation outlet assembly according to an embodiment of the disclosure.

FIG. 2 is a side view of a clamp of an embodiment of the disclosure.

FIG. 3 is a side view of an embodiment of the disclosure.

FIG. 4 is a schematic view of an embodiment of the disclosure.

### DETAILED DESCRIPTION OF THE INVENTION

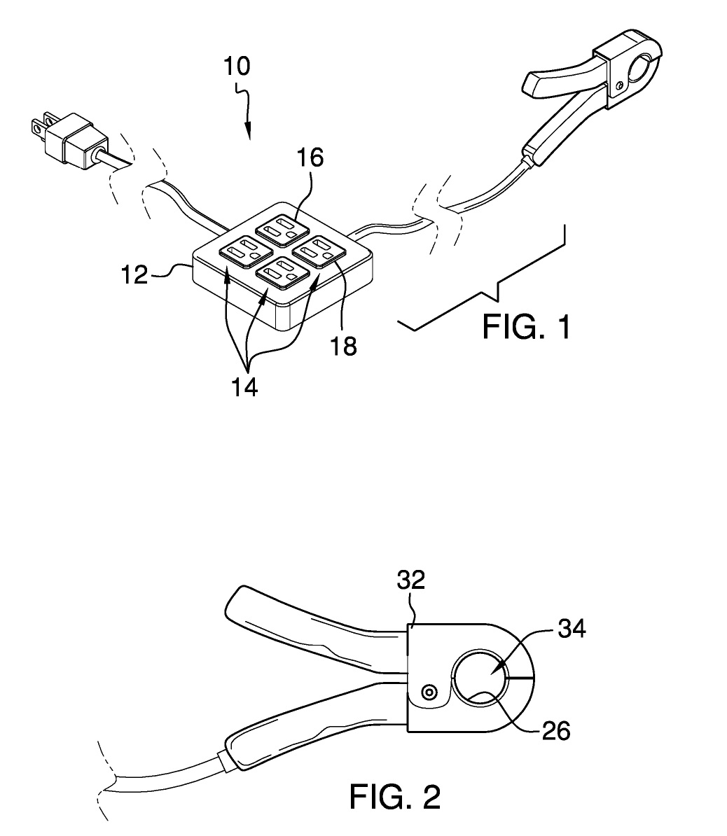

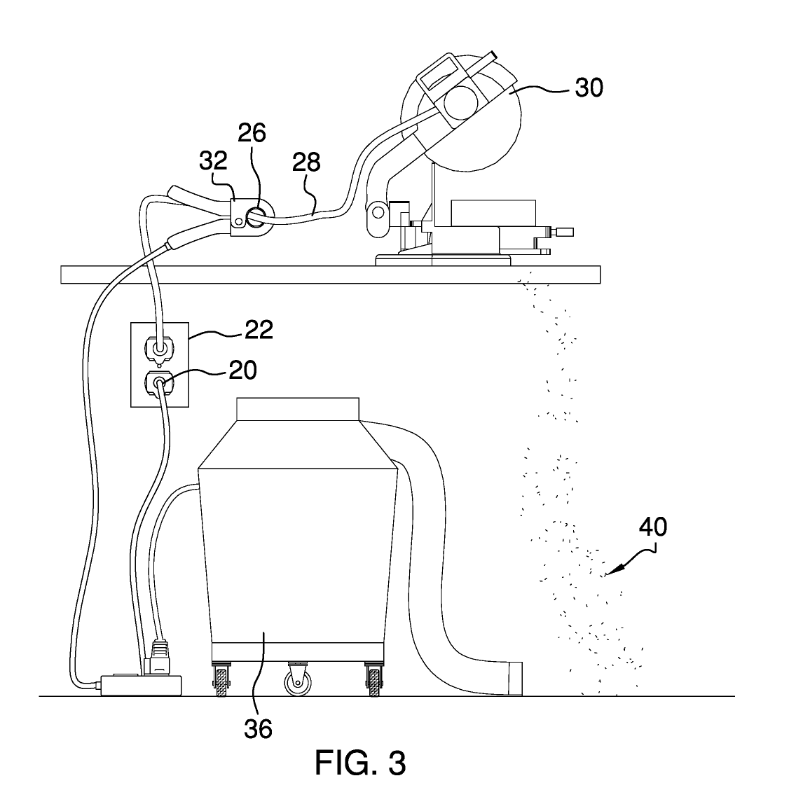

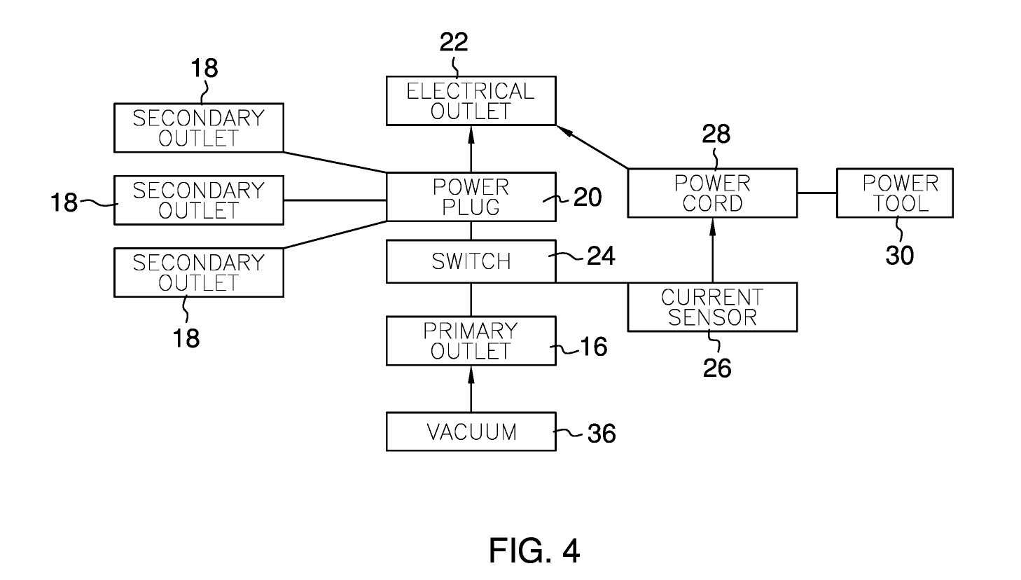

With reference now to the drawings, and in particular to FIGS. 1 through 4 thereof, a new power outlet and current sensing combination device embodying the principles and concepts of an embodiment of the disclosure and generally designated by the reference numeral 10 will be described.

As best illustrated in FIGS. 1 through 4, the power detection and activation outlet assembly 10 generally comprises a housing 12 that has a plurality of power ports 14 therein and the housing 12 may look like and overall comprise a conventional power strip to allow a person to simultaneously power multiple electric devices. The plurality of power ports 14 includes a primary outlet 16 and at least one secondary outlet 18 each being mounted in the housing 12. Generally, there will only be a single primary outlet 16 as will be understood below.

A power plug 20 is coupled to the housing 12 and is in electrical communication with each of the power ports 14. The power plug 20 is configured to be plugged into a conventional electrical outlet 22 so that electricity is thereafter supplied to the power ports 14.

A switch 24, or relay switch, is in electrical communication with the primary outlet 16. The switch 24 is in a normally closed position such that electricity is not provided to the primary outlet 16 by the power plug 20. A current sensor 26 is in electrical communication with the switch 24. The current sensor 26 actuates the switch 24 to an open position when the current sensor 26 detects a current greater than 1.0 ampere. The current sensor 26 is positioned outside of the housing 12 to facilitate positioning of the current sensor 26 on a power cord 28. Such current switches 26 may be generically known as non-invasive current sensors or spilt core current transformers. Such sensors are conventionally used to provide data as to whether or not current is flowing through a conduit. The current sensor 26 is mounted on a conventional clamp 32 having an opening 34 therein for extending the power cord 28. The clamp 32 is removably positionable on the power cord 28.

The power cord 28 is electrically coupled to a conventional power tool 30 and in particular may be coupled to a power saw or other cutting or grinding tool that produces a large amount of debris 40 and dust during usage. The power tool 30 may be plugged into a wall outlet 22, another power strip, or into one of the secondary outlets 18.

Another electrically powered device is electrically coupled to the primary outlet 16. Generally, this will be a vacuum 36 which is used for capturing the debris 40 and dust produced by the power tool 30. In use, when the power tool 30 is turned on, the current sensor 26 will detect electricity flowing through the power cord 28. When this happens, the switch 24 will be actuated to the open position so that power is supplied to the vacuum 36. This allows a user of the assembly 10 to keep a vacuum actuator in an “on” position wherein it will shut off and turn on with the power tool 30 as the current sensor opens and closes the switch 24 to power the vacuum 36. This much easier than turning on the vacuum 36, turning on the power tool 30, turning the power tool 30 off and then turning off the vacuum 28. The vacuum 36 will thereby capture the debris 40 as it is being created whenever the power tool 30 is turned on.

With respect to the above description then, it is to be realized that the optimum dimensional relationships for the parts of an embodiment enabled by the disclosure, to include variations in size, materials, shape, form, function and manner of operation, assembly and use, are deemed readily apparent and obvious to one skilled in the art, and all equivalent relationships to those illustrated in the drawings and described in the specification are intended to be encompassed by an embodiment of the disclosure.

Therefore, the foregoing is considered as illustrative only of the principles of the disclosure. Further, since numerous modifications and changes will readily occur to those skilled in the art, it is not desired to limit the disclosure to the exact construction and operation shown and described, and accordingly, all suitable modifications and equivalents may be resorted to, falling within the scope of the disclosure. In this patent document, the word “comprising” is used in its non-limiting sense to mean that items following the word are included, but items not specifically mentioned are not excluded. A reference to an element by the indefinite article “a” does not exclude the possibility that more than one of the element is present, unless the context clearly requires that there be only one of the elements.

I claim:

1. A power outlet and current sensor combination comprising:
a housing having a plurality of power ports therein, said plurality of power ports including a primary outlet and at least one secondary outlet being mounted in said housing;
a power plug being coupled to said housing and being in electrical communication with each of said power ports, said power plug being configured to be plugged into an electrical outlet;
a switch being in electrical communication with said primary outlet, said switch being in a normally closed position such that electricity is not provided to said primary outlet by said power plug; and
a current sensor being in electrical communication with said switch, said current sensor actuating said switch to an open position when said current sensor detects a current greater than 1.0 ampere, said current sensor being positioned outside of said housing to facilitate positioning of said current sensor on a power cord.

2. The power outlet and current sensor combination according to claim 1, further including a clamp, said current sensor being mounted on said clamp, said clamp being removably positionable on the power cord.

3. The power outlet and current sensor combination according to claim 1, further including:
said power cord being electrically coupled to a power tool;
a vacuum being electrically coupled to said primary outlet; and
said current sensor detecting current when said power tool is turned on such that said switch is actuated to said open position such that electricity is supplied to said vacuum.

4. A power outlet and current sensor combination system comprising:
a housing having a plurality of power ports therein, said plurality of power ports including a primary outlet and at least one secondary outlet being mounted in said housing;
a power plug being coupled to said housing and being in electrical communication with each of said power ports, said power plug being configured to be plugged into an electrical outlet;
a switch being in electrical communication with said primary outlet, said switch being in a normally closed position such that electricity is not provided to said primary outlet by said power plug;
a current sensor being in electrical communication with said switch, said current sensor actuating said switch to an open position when said current sensor detects a current greater than 1.0 ampere, said current sensor being positioned outside of said housing to facilitate positioning of said current sensor on a power cord;
a clamp, said current sensor being mounted on said clamp, said clamp being removably positionable on the power cord;
said power cord being electrically coupled to a power tool;
a vacuum being electrically coupled to said primary outlet; and
said current sensor detecting current when said power tool is turned on such that said switch is actuated to said open position such that electricity is supplied to said vacuum.
